(19) United States
(12) Patent Application Publication
(10) Pub. No.: US 2004/0153937 A1
(43) Pub. Date: Aug. 5, 2004

(54) Video error compensating method and apparatus therefor

(75) Inventor: Ki Woong Moon, Daegu (KR)

Correspondence Address: FLESHNER & KIM, LLP, P.O. BOX 221200, CHANTILLY, VA, 20153, US

(73) Assignee: LG ELECTRONICS INC.

(21) Appl. No.: 10/702,601

(22) Filed: Nov. 7, 2003

(30) Foreign Application Priority Data
Nov. 8, 2002 (KR) KR69337/2002

(51) Int. Cl. H04L 1/00; G06F 11/00; G06F 11/30; H03M 13/00; G08C 25/00

(52) U.S. Cl. 714/746

(57) ABSTRACT

A method for processing video includes performing two error-detecting steps for a video bit stream. In the first step, the video bit stream is compared a code book. If no error is detected, the second step includes determining whether a discontinuity exists between adjacent macroblocks in the video bit stream. If a discontinuity is detected to exist, error compensation is performed prior to display of the video bit stream. A discontinuity between or among adjacent macroblocks is preferably detected by comparing one or more color values derived from the macroblocks. The color values may include a chrominance value and a luminance value. Difference values derived from the comparisons are measured against respective threshold values and the outcome determines whether a discontinuity exists. A system for processing video includes two detectors for respectively performing the error detecting steps and at least one compensation circuit for compensating the video bit stream for the detected errors.

### BACKGROUND OF THE INVENTION

1. Field of the Invention

The present invention generally relates to video systems, and in particular to a method and an apparatus for compensating error in a video system.

2. Description of the Related Art

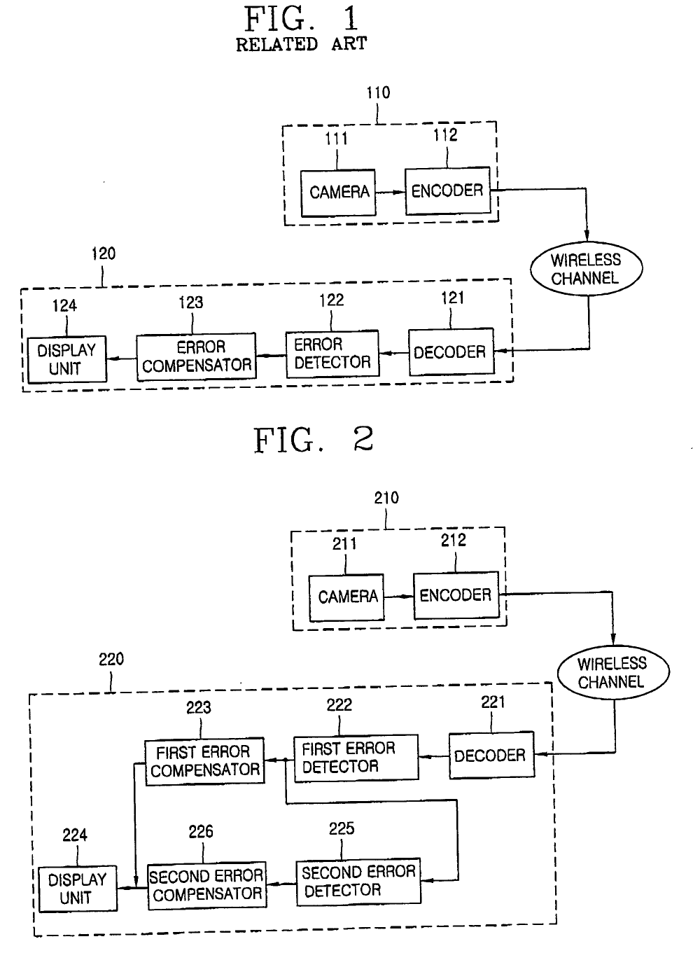

FIG. 1 shows a video system in accordance with the related art. This, the video system includes a transmitting unit 110 for transmitting a video bit stream through a wireless channel and a receiving unit 120 for displaying an image by decoding the video bit stream received through the wireless channel.

The transmitting unit 110 includes a camera 111 for photographing video and an encoder 112 for encoding the video photographed by the camera by a H.263 standard and generating a video bit stream. The H.263 is an International standard used for compressing a video part of a multimedia communication service such as a video conference, video telephone, etc. through a communication channel having a low transmission rate. The H.263 is described in U.S. Pat. No. 6,560,280.

The receiving unit 120 includes a decoder 121, an error detector 122, an error compensator 123, and a display unit 124. The decoder decodes a video bit stream received through the wireless channel in an MPEG (moving picture experts group) or H.263 standard. The error detector detects error from the decoded video bit stream. The error compensator compensates the detected error. And, the display unit displays the error-compensated video bit stream (video signal) on a screen. A video error compensating apparatus in accordance with the related art includes the error detector 122 and the error compensator for compensating the detected error.

Operation of the video system will now be described. First, the transmitting unit 110 generates a video bit stream by encoding a video signal received from the camera 111 in accordance with an MPEG or H.263 standard using encoder 102. The generated video bit stream is then transmitted to the wireless channel. In forming the stream, the encoder 102 encodes the video signal by MB (macroblock) units. Herein, a bitstream syntax of the H.263 standard is divided into four layers. More specifically, a block layer of 8×8 (pixels) is the lowest layer, a macroblock layer consists of six block layers (four luminance layers, two chrominance layers), and one GOB (group of block layer) consists of the several macroblock layers. And, one picture layer consists of the several GOBs.

The decoder 121 of the receiving unit 120 decodes the video bit stream received through the wireless channel in the MPEG or H.263 standard. The decoded video bit stream is then output to the error detector 122. The detector detects error from the decoded video bit stream with reference to a code book and outputs the detected error to the error compensator 123. A code book of this type is described in U.S. Pat. No. 5,768,438.

The error compensator 123 compensates error by concealing a macroblock at which an error is detected, and it displays the error compensated-decoded video bit stream (video signal) on a screen through the display unit 124. The concealment involves replacing the macroblock in which the error is detected with a previously decoded macroblock or a current macroblock. More specifically, the error compensation has to be performed without exception in the video communication through a wireless channel in which error occurs frequently, and an error concealment technique is one of error compensation methods. Error concealment is described in U.S. Pat. No. 6,078,616.

When there is no index about a pertinent video bit stream with reference to the code book, the related-art error detector detects the pertinent video bit stream as error. More specifically, when there is no index about the pertinent video bit stream, the pertinent video bit stream is judged as an invalid code. Actually, when error occurs in a video bit stream, because the possibility of misconceiving an error is much greater than the ‘invalid code’-judging probability, the related-art error detecting technique using ‘invalid code’ may not detect error, although it may detect error, error is detected always behind time due to variable length coding characteristics.

Table 1 shows the occurrence probability of an invalid code not in the code book in a system operating in accordance with the H.263 standard.

TABLE 1

| | | | Probability |
|---|---|---|---|
| | The Number of | The Number of | of Invalid |
| Code Book Type | Codes | Invalid Codes | Code Occurrence |
| MCBPC Code Book | 8192 | 9 | 0.110% |
| about P-frame | | | |
| MCBPC Code Book | 512 | 7 | 1.37% |
| about I-frame | | | |
| CBPY Code Book | 64 | 2 | 3.125% |
| MVD Code Book | 81924 | 5 | 0.061% |
| TCOEFF Code | 81924 | 16 | 0.195% |
| Book | | | |

In the Table, the MCBPC standard for “MB Type & Coded Block Pattern for Chrominance”, CBPY stands for “Coded Block Pattern for Luminance”, MVD stands for “Motion Vector Data”, and TCOEFF stands for ‘Transform Coefficient’.

In view of the foregoing discussion, there are at least three drawbacks of the related-art. First, when there is an index about a video bit stream in which error occurs, it is judged that there is no error in the video bit stream, and accordingly the error occurrence position cannot be detected. Second, because of variable length coding characteristics in which even resynchronization marker is affected by error, although error is detected, because error is always detected after passing the actual error occurrence position, there are plural green-pink blocks in the decoded video due to error. Accordingly, picture quality is lowered. Third, when it comes to the probability of invalid code occurrence in the H.263 standard, it is impossible to detect all errors about all video bit streams.

### SUMMARY OF THE INVENTION

An object of the present invention is to solve one or more drawbacks of the related art and/or to achieve at least one and preferably all of the following advantages. Another object of the present invention is to provide a method and apparatus for compensating video error by detecting discontinuities between or among decoded adjacent macroblocks.

In order to achieve the above-mentioned objects, a video error compensating method includes detecting error from a video bit stream decoded by macroblock units with reference to a code book; compensating the detected error; detecting continuous between a current macroblock of a video bit stream in which the error is not detected and adjacent macroblocks; and concealing the current macroblock when continuous is not detected.

A video error compensating apparatus includes a decoder for decoding a video bit stream encoded by macroblock units; a first error detector for detecting error from the decoded video bit stream with reference to a code book; a first error compensator for compensating error detected by the first error detector; a second error detector for detecting error from a video bit stream in which error is not detected by the first error detector on the basis of continuous between a current macroblock of a decoded video bit stream in which error is not detected by the first error detector and adjacent macroblocks of the current macroblock; and a second error compensator for compensating error detected by the second error detector.

BRIEF DESCRIPTION OF THE DRAWINGS

FIG. 1 is a block diagram illustrating a construction of a video system in accordance with the related art;

FIG. 2 is a block diagram illustrating a construction of a video system using a video error compensating apparatus in accordance with one embodiment of the present invention;

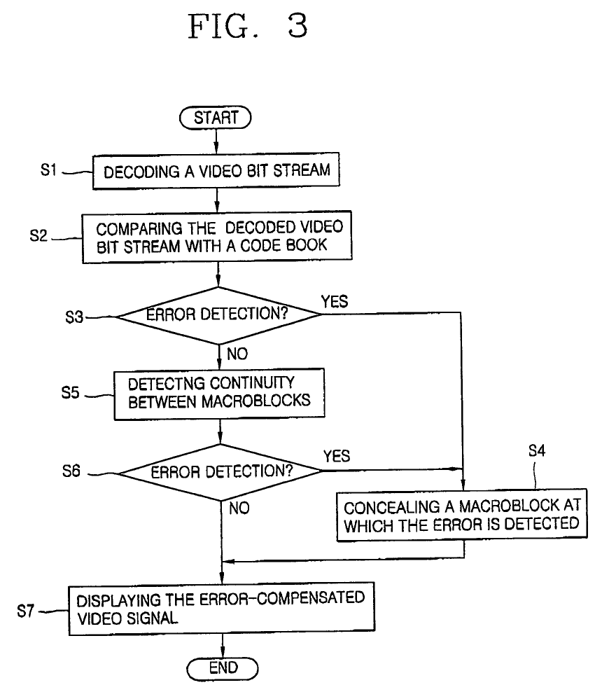

FIG. 3 is a flow chart illustrating steps included in a video error compensating method in accordance with one embodiment of the present invention;

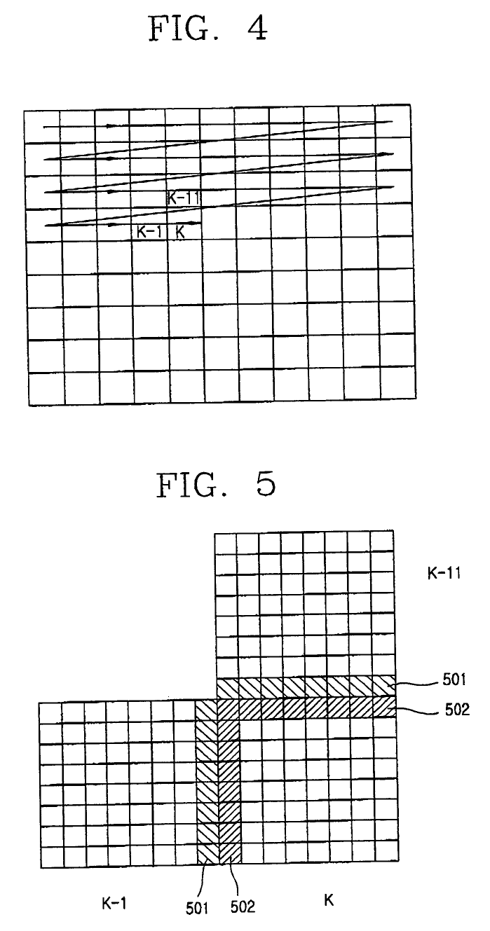

FIG. 4 illustrates a preferred decoding order of macroblocks in accordance with the present invention;

FIG. 5 illustrates a currently decoded macroblock and spatially adjacent macroblocks which may be compared in accordance with the present invention for purposes of detecting discontinuity errors;

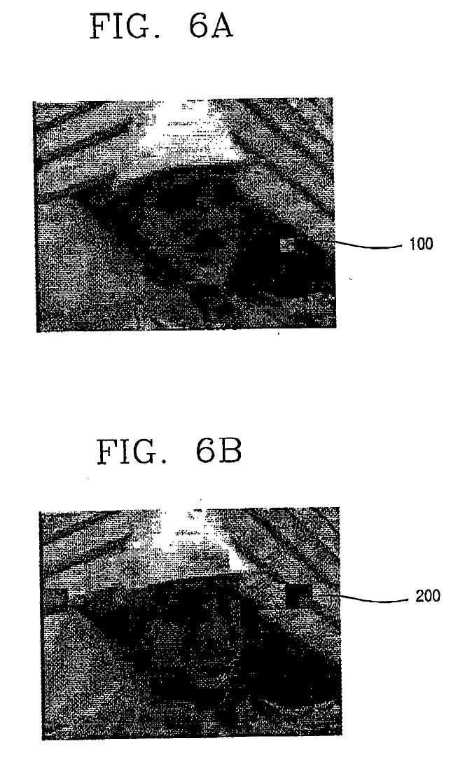

FIGS. 6A and 6B illustrate images restored by a video error detector in accordance with the related art; and

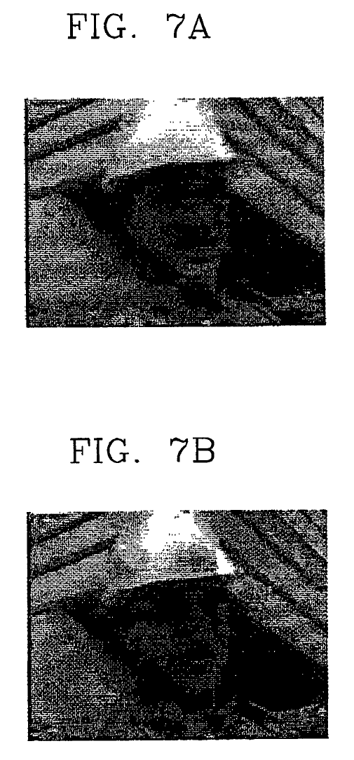

FIGS. 7A and 7B illustrate images restored by a video error detector in accordance with one or more of the foregoing embodiments of the present invention.

### DETAILED DESCRIPTION OF THE PREFERRED EMBODIMENT

The method and apparatus for compensating video error in accordance with the present invention improves picture quality compared to related art systems and methods. This is accomplished by detecting error from a decoded video bit stream with reference to a code book, compensating the detected error for a first time time, concealing a current macroblock when there is no continuity between the a current macroblock of the decoded video bit stream and adjacent macroblocks, compensating error in the decoded video bit stream for a second time time, and then displaying the decoded (twice-error-compensated) video bit stream on a screen. Herein, when there is no continuity between a current macroblock of the decoded video bit stream and adjacent macroblocks, the current macroblock is a “green-pink block”. More specifically, in accordance with the present invention, by detecting error from the decoded video bit stream with reference to the code book, the error is compensated, by concealing the green-pink block. As a result, picture quality of the video is improved.

FIG. 2 shows a video system with uses a video error compensating apparatus in accordance with one embodiment of the present invention. This system includes a transmitting unit 210 for transmitting a video bit stream through a wireless channel and a receiving unit 220 for decoding the video bit stream received through the wireless channel and displaying the video.

The transmitting unit 210 includes a camera 211 for photographing or capturing video) and an encoder 212 for encoding the video photographed or captured by the camera. Preferably in the H.263 standard and generating a corresponding video bit stream. The camera and encoder may perform the same functions or those of the related art.

The receiving unit 220 includes a decoder 221 a first error detector 222, a first error compensator 223, a display unit 224, a second error detector 225, and a second error compensator. The decoder decodes the video bit stream received through the wireless channel by an MPEG (moving picture experts group) or H.263 standard. The first error detector detects error from the decoded video bit stream with reference to a code book. The first error compensator compensates the error detected by the first error detector. The second error detector detects error from the decoded video bit stream which is not detected by the first error detector on the basis of continuity between a current macroblock of the decoded video bit stream and one or mote adjacent macroblocks. The second error compensator compensates error detected by the second error detector. And, the display unit displays the video bit stream (video signal) which has been error-compensated by the first and error compensators on a screen.

The second error detector 225 detects continuity between a current decoded macroblock of the video bit stream in which error is not detected by the first error detector and one or mote adjacent macroblock. When there is no continuity, the current decoded macroblock is judged to be in error. For example, when continuity between a current decoded macroblock of the video bit stream in which error is not detected and one or more adjacent macroblocks thereof is detected, the second error detector compares luminance Y and chrominance Cr/Cb with each other and one or more MAD values of the luminance and chrominance are compared with respective present reference values. When the MAD value(s) is/are not less than the reference value(s), the current macroblock of the video bit stream in which the error is not detected is judged as error. In addition, the second error compensator 226 conceals the macroblock judged by the second error detector as error.

The video error compensating apparatus of the video system in accordance with the present invention includes the first error detector, the first error compensator 223, the second error detector 225, and the second error compensator 226. In addition, in the present invention, the first error compensator 223 and the second error compensator 226 are described as independent parts. However, it is also possible to construct them as one error compensator.

FIG. 3 is a flow chart showing steps included in a video error compensating method in accordance with one embodiment of the present invention. The method performs two error detection/error compensation steps. First, the method detects error from a macroblock unit in the decoded video bit stream with reference to a code book and then compensates the error by concealing a macroblock in which the error is detected. Second, the method detects continuity between a current macroblock for which error has not been error detected in the video bit stream and one or more adjacent macroblocks and then conceals the current macroblock when there is no continuity. By taking this approach and accordingly it is possible to eliminate the “green-pink phenomenon” which occurs in the related-art video error compensating apparatus.

More specifically, the method begins when, the transmitting unit 210 generates a video bit stream by encoding a video signal from the camera 211 using the MPEG or H.263 standard through the encoder 202. The encoder preferably generates the video bit stream by encoding the video signal by the MB (macroblock) units. The generated video bit stream is then transmitted through the wireless channel.

The decoder 221 of the receiving unit decodes the encoded video bit stream received from the wireless channel in the MPEG or H.263 standard, and outputs the decoded video bit stream to the first error detector 222 as shown at step S1.

The first error detector 222 detects error from the decoded video bit stream with reference to the code book for a first time and outputs the first-detected error to the first error compensator 223. More specifically the first error detector detects error from the decoded video bit stream for the first time by comparing the decoded video bit stream with the code book as shown at step S2.

When error is detected by the first error detector 222 as shown at step S3, the first error compensator 223 compensates the first-detected error and outputs the error-compensated video bit stream (video signal) to the display unit 224. The first error compensator 223 compensates the error preferably by concealing the macroblock at which the error is detected as shown at step S4.

Afterward, the second error detector 225 detects error in a currently decoded macroblock of a video bit stream in which error was not detected among the video bit screams output from the first error detector 222.

FIG. 4 illustrates a preferred decoding order of a macroblock. More specifically, FIG. 4 shows a QCIF (quarter common intermediate format) 4:2:0 format (Y:176×144 pixels, Cr/Cb: 88×72 pixels). Where, Y means luminance and Cr/Cb means chrominance. In FIG. 4, K indicates a position of a currently decoded macroblock, and the arrows indicate a decoding order of previously decoded macroblocks (K-11, K-1, K).

FIG. 5 shows a currently decoded macroblock and spatially adjacent macroblocks. More specifically, in accordance with the present invention. By using the basic concept of video signal processing and compressing as “a video signal in the natural world is not changed instantly at a temporally spatially adjacent position”, video error is detected. For example, when there is a video bit stream in which error is not detected by the first error detector 222, in order to detect whether a K-th macroblock, in which error was not detected in the video bit stream, is a “green-pink macroblock”, continuity is detected at a boundary between the K-th macroblock and one or more adjacent macroblocks (K-1, K-11) (501, 502 in FIG. 5). More specifically, in decoding the video signal encoded in macroblock units, when a differential value between the currently decoded macroblock and one or more of the previously decoded adjacent macroblock is large and, for example, above a predetermined threshold level, the currently decoded macroblock is judged as error as shown at step S5.

Continuity between the currently decoded macroblock and the previously decoded adjacent macroblocks is preferably detected based on a MAD (mean absolute difference) in accordance with Equations 1-3.

$$\begin{matrix}\begin{matrix}{MAD}_{y} ( k ) = \frac{1}{16} {\sum }_{j = 0}^{15} \vert {Y}_{k} ( 0 , j ) - {Y}_{k - 1} ( 15 , j ) \vert + \\ \frac{1}{16} {\sum }_{i = 0}^{15} \vert {Y}_{k} ( i , o ) - {Y}_{k - 1} ( i - 15 ) \vert\end{matrix} & ( 1 ) \\ \begin{matrix}{MAD}_{Cb} ( k ) = \frac{1}{8} {\sum }_{j = 0}^{7} \vert {Cb}_{k} ( 0 , j ) - {Cb}_{k - 1} ( 7 , j ) \vert + \\ \frac{1}{8} {\sum }_{i = 0}^{7} \vert {Cb}_{k} ( i , o ) - {Cb}_{k - 1} ( i - 7 ) \vert\end{matrix} & ( 2 ) \\ \begin{matrix}{MAD}_{Cr} ( k ) = \frac{1}{8} {\sum }_{j = 0}^{7} \vert {Cr}_{k} ( 0 , j ) - {Cr}_{k - 1} ( 7 , j ) \vert + \\ \frac{1}{8} {\sum }_{i = 0}^{7} \vert {Cr}_{k} ( i , o ) - {Cr}_{k - 1} ( i - 7 ) \vert\end{matrix} & ( 3 )\end{matrix}$$

Yₖ(i,j) is an i, j pixel value of a k-th macroblock of a Y (luminance) signal, where i is a coordinate of the horizontal axis of the macroblock, and the j is a coordinate of the vertical axis of the macroblock.

When the first error detector does not detect error in a video bit stream, the video bit stream is input into the second error detector. The second error detector then performs error detection about the currently decoded k-th macroblock (MB) on the basis of the MAD defined as Equations 1-3 using Equation 4.

if MAD_{Y}(k)≧TH_{Y}, then kₜₕ MB is an errored MB

if MAD_{Cb}(k)≧TH_{Ch}, then kₜₕ MB is an errored MB

if MAD_{Cr}(k)≧TH_{Cr}, then kₜₕ MB is an errored MB (4)

The threshold values may be selected to be any one of a variety of values. Preferably, Th_{Y}=70, Th_{Cb},Th_{Cr}=50. When error detection is performed for the currently decoded k-th macroblock (MB), a MAD value (MAD_{Y},MAD_{Cb},MAD_{Cr}) of each color signal in a green-pink macroblock is indicative of a discontinuity. This corresponds to a situation where the MAD value is greater than the threshold value, e.g., at least on of MAD_{y}, MAD_{cb}, MAD_{cr} is greater than their respective threshold values Th_{y}, Th_{cb}, and Th_{cr}. If desired, more than one or all of MAD_{y}, MAD_{cb}, and MAD_{cr} may be required to be greater than their respective threshold values before an error is detected to exist. On the contrary, a MAD value of a normal macroblock which does not have an error is less than a threshold value, as video in the natural world is continuous, e.g., all three of MAD_{y}, MAD_{cb}, and MAD_{cr} are less than Th_{y}, Th_{cb}, and Th_{cr}. Respectively, although only some or one of them can be less if desired.

The second error detector 225 thus compares luminance Y and chrominance Cr/Cb between adjacent blocks, compares the compared luminance and chrominance MAD value with a preset reference or threshold value, when the MAD value is not less than the reference value, the second error detector 225 judges it as error. The second error detector 225 performs this error detection function for a video bit stream which was detected not to have an error by the first error detector 222 on the basis of Equations 1-4 More specifically, the second error detector 225 detects a “green-pink macroblock-” from a video bit stream which was indicated to not have an error by the first error detector 222 on the basis of Equations 1-4.

When error is detected by the second error detector 225, the second error compensator 226 compensates the error by concealing the macroblock (green-pink macroblock) at which the error is detected. Compensator 226 then outputs the error-compensated video bit stream to the display unit 224 as shown at step S6.

When error is not detected by the second error detector 225, the second error compensator 226 outputs a video bit stream having a macroblock in which error is not detected to the display unit 224.

The display unit 224 displays the video bit stream error compensated-decoded by the first and second error compensators 223, 226 on the screen as shown at step S7. More specifically, in accordance with the present invention, by compensating a detected error for a first time and compensating error for a second time on the basis of continuity between a current macroblock of a video bit stream in which error is not detected in the first detection and adjacent blocks, picture quality-improved video can be displayed.

FIGS. 6A and 6B and FIGS. 7A and 7B compare examples of video restored by the related-art video error detector and video restored by the video error detector of the present invention. More specifically, FIGS. 6A and 6B illustrate images restored by a video error detector in accordance with the related art. As shown, these images include a green-pink macroblock. FIGS. 7A and 7B illustrate images restored by a video error detector in accordance with the present invention. These images do not include a green-pink macroblock.

As depicted, when video is restored by the related-art error detecting method, green-pink macroblocks 100 and 200 occur in the restored video. However, in the present invention, by concealing a current macroblock in which error is detected, as depicted in FIGS. 7A and 7B, a green-pink macroblock does not occur. Mote specifically, by using the video error compensating apparatus in accordance with the present invention for a video system, as depicted in FIGS. 7a and 7B, picture quality-improved video can be displayed.

In the present invention, a bit stream in which error is injected into a Foreman video bit stream encoded as 48 kbps, 15 fps by using a BER (bit error rate)=10³ among error patterns provided by ITU-T is used as a test data.

As described-above, in the video error compensating apparatus and method in accordance with the present invention, by detecting error from the decoded video bit stream with reference to a code book and compensating the error, by detecting a green-pink block from a video bit stream in which error is not detected and concealing the detected green-pink block, picture quality of video can be improved.

What is claimed is:

1. A video error compensating method, comprising:
detecting error in a video bit stream decoded by macroblocks with reference to a code book;
compensating the detected error if error is detected;
if error is not detected, detecting whether a discontinuity exists between a current macroblock of the video bit stream and one or more adjacent macroblocks; and
concealing the current macroblock when a discontinuity is detected.

2. The method of claim 1, wherein the compensating step includes concealing a macroblock at which the error is detected.

3. The method of claim 1, wherein detecting whether a discontinuity exists includes:
comparing at least one of luminance and chrominance of the current and one or more adjacent blocks;
comparing a MAD value derived from the comparison of one of the luminance and chrominance with a preset reference values; and
judging that the current macroblock has a discontinuity based on the comparison of the MAD value and the reference value.

4. A video error compensating apparatus, comprising:
a decoder which decodes a video bit stream encoded by macroblock units;
a first error detector whether error exists in the decoded video bit stream with reference to a code book;
a first error compensator which compensates error detected by the first error detector;
a second error detector which detects error in the video bit stream when no error was detected by the first error detector, the second error detector detecting error by determining whether a discontinuity exists between a current macroblock of the video bit stream and one or more adjacent macroblocks; and
a second error compensator which compensates error detected by the second error detector.

5. The apparatus of claim 4, further comprising:
a display unit which displays on a screen a video bit stream in which error is compensated by one of the first and second error compensators.

6. The apparatus of clam 4, wherein the first error compensator conceals a macroblock at which error is detected by the first error detectors and the second error detector conceals the current macroblock when a discontinuity is detected.

7. The apparatus of claim 4, wherein the second error compensator conceals a macroblock at which error is detected by the second error detector.

8. A method for processing video, comprising:
detecting a discontinuity between adjacent macroblocks in a video bit stream; and
compensating for the discontinuity in the video bit steam.

9. The method of claim 8, wherein detecting a discontinuity includes:
comparing color values of the adjacent macroblocks; and
determining chat a discontinuity exists based on a result of the comparison.

10. The method of claim 9, wherein the color values are luminance values.

11. The method of claim 9, wherein the color values are chrominance values.

12. The method of claim 9, wherein determining that the discontinuity exists includes:
computing a difference value based on the comparison of the color values; and
comparing the difference value to a predetermined threshold.

13. The method of claim 8, wherein detecting a discontinuity includes:
comparing first color values and second color values of the adjacent macroblocks; and
determining that a discontinuity exists based on a result of the comparison.

14. The method of claim 13, wherein the comparing step includes:
computing a first difference value equal to a difference between the first color values;
computing a second difference value equal to a difference between the second color values;
comparing the first difference value and the second difference value to respective threshold values.

15. The method of claim 13 wherein the determining step includes:
determining that a discontinuity exists if at least one of the first and second difference values exceed their respective threshold values.

16. The method of claim 13 wherein the determining step includes:
determining that no discontinuity exists if the first and second difference values are both less than their respective threshold values.

17. The method of claim 8, wherein compensating for the discontinuity includes:
concealing one of the adjacent macroblocks from display.

18. The method of claim 8, wherein the video bit stream conforms to an H.263 standard.

19. A system for processing video, comprising:
a detector which detects a discontinuity between adjacent macroblocks in a video bit stream; and
a compensator which compensates for the discontinuity in the video bit stream.

20. The system of claim 19, wherein the detector compares color values of the adjacent macroblocks and determines that a discontinuity exists based on a result of the comparison.

21. The system of claim 20, wherein the color values are luminance values.

22. The system of claim 20, wherein the color values are chrominance values.

23. The system of claim 20, wherein the detector determines that a discontinuity exists by computing a difference value based on the comparison of the color values and comparing the difference value to a predetermined threshold.

24. The system of claim 19, wherein the detector compares first color values and second color values of the adjacent macroblocks and determines that a discontinuity exists based on a result of the comparison.

25. The system of claim 24, wherein the detector computes a first difference value equal to a difference between the first color values, computes a second difference value equal to a difference between the second color values, and compares the first difference value and the second difference value to respective threshold values.

26. The system of claim 25, wherein the detector determines that a discontinuity exists if at least one of the first and second difference values exceed their respective threshold values.

27. The system of claim 25, wherein the detector determines that no discontinuity exists if the first and second difference values are both less than their respective threshold values.

28. The system of claim 19, wherein the compensator conceals one of the adjacent macroblocks from display.

29. The system of claim 19, wherein the video bit stream conforms to an H.263 standard.

30. A method for processing video, comprising:
comparing a video bit stream to a code book;
determining whether an error exists in the video bit stream based on the comparison;
if no error is determined to exist, detecting a discontinuity between adjacent macroblocks in the video bit stream; and
compensating for the discontinuity.

31. The method of claim 30, wherein detecting a discontinuity includes:
comparing color values of the adjacent macroblocks; and
determining that a discontinuity exists based on a result of the comparison.

32. The method of claim 31, wherein the color values are luminance values.

33. The method of claim 31, wherein the color values are chrominance values.

34. The method of claim 31, wherein determining that a discontinuity exists includes:
computing a difference value based on the comparison of the color values; and
comparing the difference value to a predetermined threshold.

35. The method of claim 30, wherein detecting the discontinuity includes:
comparing first color values and second color values of the adjacent macroblocks; and
determining that a discontinuity exists based on a result of die comparison.

36. The method of claim 35, wherein the comparing step includes:
computing a first difference value equal to a difference between the first color values;
computing a second difference value equal to a difference between the second color values;
comparing the first difference value and the second difference value to respective threshold values.

37. The method of claim 35 wherein the determining step includes:
determining that a discontinuity exists if at least one of the first and second difference values exceed their respective threshold values.

38. The method of claim 35 wherein the determining step includes:
determining that no discontinuity exists if the first and second difference values are both less than their respective threshold values.

39. The method of claim 30, wherein compensating for the discontinuity includes:
concealing one of the adjacent macroblocks from display.

40. The method of claim 30, wherein the video bit stream conforms to an H.263 standard.

41. A system for processing video, comprising:
a first detector which determines whether an error exists in a video bit stream by comparing the video bit stream to a code book;
a second detector which detects a discontinuity between adjacent macroblocks in the video bit stream if no error is detected by the first detector; and
a compensator which compensates for the discontinuity.
